(19) United States
(12) Patent Application Publication
(10) Pub. No.: US 2015/0270367 A1
(43) Pub. Date: Sep. 24, 2015

(54) Ultra Low Power Transistor for 40nm Processes

(71) Applicant: Cambridge Silicon Radio Limited, Cambridge (GB)

(72) Inventors: David Vigar, Cambridge (GB); Dave Verity, Cambridge (GB); Rainer Herberholz, Cambridge (GB)

(21) Appl. No.: 14/560,504

(22) Filed: Dec. 4, 2014

(30) Foreign Application Priority Data
Mar. 24, 2014 (GB) 1405181.7

(51) Int. Cl. H01L 29/66

(52) U.S. Cl. CPC H01L 29/6659; H01L 29/66492

(57) ABSTRACT

Methods of fabricating ultra-low power transistors are described using advanced technology nodes (e.g. 40 nm or less). In an embodiment, by optimizing a MOSFET to a different point, i.e. for low junction off (or leakage) current rather than speed/on current, a MOSFET can be produced which still meets the HCl reliability specification but has significantly reduced power consumption when off, e.g. half to one third of the standard off current. At this new optimisation point, the LDD dose is reduced to a level (e.g. 10-20% of the standard LDD dose) such that if it is reduced further, the device will no longer pass the HCl reliability specification. This is in contrast to standard MOSFETs which are optimized for speed/on current and have an LDD dose which, if increased further, would cause the device to no longer pass the HCl reliability specification.

### BACKGROUND

The ‘Internet of Things’ (IoT) envisages the use of many standalone sensors to detect the environment, track objects etc. that will communicate wirelessly with a host computing device (e.g. a smartphone) which is connected to the internet. A suitable short range wireless technology for making this connection is Bluetooth® Smart (or Bluetooth Low Energy, BLE). As the stand alone sensors are battery powered, there is a need to reduce the power consumption of Bluetooth® Smart chips in order to extend the battery life of the devices in which they are incorporated. Active power consumption may be improved by moving to smaller dimension technology nodes when fabricating the chips, for example 40 nm, 28 nm, etc. The term ‘technology node’ refers to the process used to fabricate chips, with the dimension typically specifying the minimum gate length (although it may refer to other features).

The embodiments described below are not limited to implementations which solve any or all of the disadvantages of known transistors.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Methods of fabricating ultra-low power transistors are described using advanced technology nodes (e.g. 40 nm or less). In an embodiment, by optimizing a MOSFET to a different point, i.e. for low junction off (or leakage) current rather than speed/on current, a MOSFET can be produced which still meets the HCl reliability specification but has significantly reduced power consumption when off, e.g. half to one third of the standard off current. At this new optimisation point, the LDD dose is reduced to a level (e.g. 10-20% of the standard LDD dose) such that if it is reduced further, the device will no longer pass the HCl reliability specification. This is in contrast to standard MOSFETs which are optimized for speed/on current and have an LDD dose which, if increased further, would cause the device to no longer pass the HCl reliability specification.

A first aspect provides a method of fabricating a MOSFET using a CMOS technology node of 40 nm or less, the technology node comprising a first optimization point for LDD implant dose and a second optimization point for LDD implant dose, the first optimization point comprising a maximum LDD implant dose that satisfies an HCl reliability requirement and the second optimization point comprising a minimum LDD implant dose that satisfies the same HCl reliability requirement and the method comprising: forming pocket implants in a MOSFET structure; and forming LDD implants in the MOSFET structure using an LDD implant dose at the second optimization point.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 is a graph showing effective leakage against device speed for various different dimension technology nodes;

FIG. 2 is a schematic diagram of a cross-section through a MOSFET;

FIG. 3 is a graph showing the hot carrier injection (HCl) lifetime against the LDD dose; and

FIG. 4 is a graph which shows example results of making the changes to the MOSFET fabrication process as described herein.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

As described above, there is a need to reduce the power consumption of short range wireless chips, such as Bluetooth® Smart (or BLE), in order to extend the battery life of devices in which they are incorporated. Use of smaller dimension technology nodes (e.g. 40 nm, 28 nm, etc, which collectively may be referred to as ‘advanced technology nodes’) for the CMOS processes used to fabricate the chips reduces the active power consumption (i.e. the power consumption when the device is active); however, chips used in these applications are unusual because they spend a large percentage of their time (e.g. 98%) in standby modes. In an example, a device may wake for only 1 ms in every second to poll a central device and/or receive a packet from that device in order to maintain the presence of the device within network.

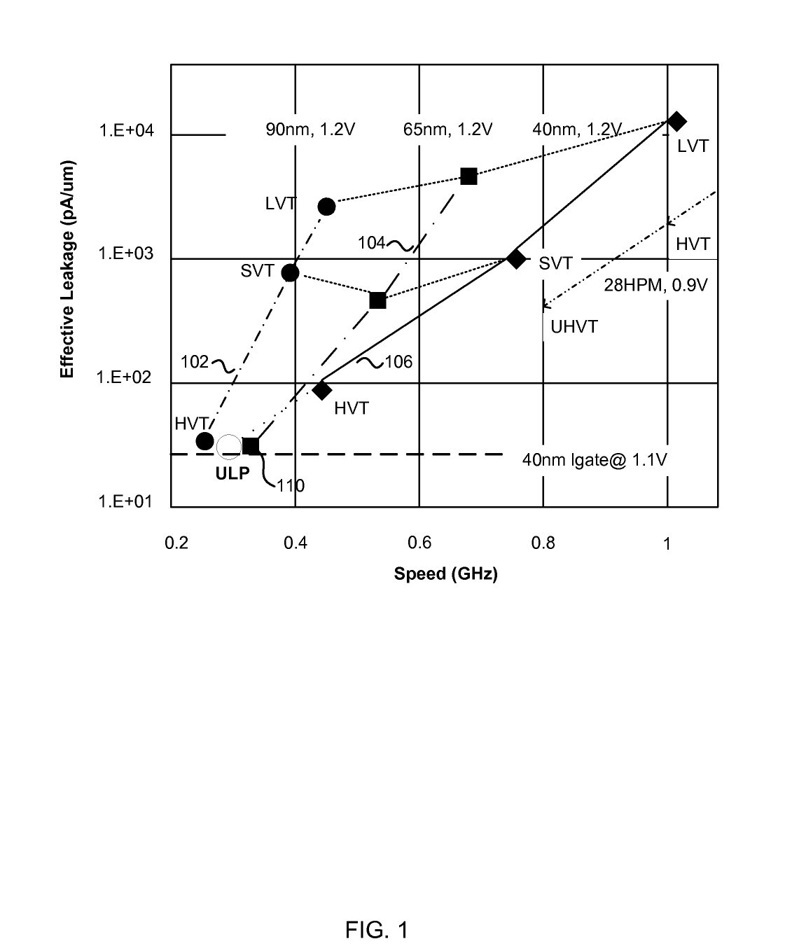

As these devices typically spend the majority of their time in standby mode, the active power consumption is no longer the dominant consumer of power and instead the power consumption when in the standby state becomes the dominant factor. The smaller dimension technology nodes (e.g. the advanced technology nodes) typically have higher leakage currents in the off state and hence higher power consumption in standby modes of operation, as shown in FIG. 1. FIG. 1 is a graph showing effective leakage (on the y-axis) against device speed (on the x-axis) for various different dimension technology nodes: 90 nm (arrow 102), 65 nm (arrow 104), 40 nm (arrow 106) and 28 nm (arrow 108).

As can be seen from the graph in FIG. 1, one way to improve the power consumption of a chip in standby modes of operation is to move to a larger dimension technology node (e.g. to move away from 40 nm to 65 nm or 90 nm). However, as also shown in FIG. 1, there may be other reasons that a smaller dimension technology node (e.g. 40 nm or smaller) is required, such as the speed of devices (as is clearly shown in FIG. 1, as the dimension of the technology node decreases, the device speed increases) or active power (e.g. 40 nm has lower active power than 65 nm).

Methods of fabricating a transistor are described below which can be used to produce an ultra-low power (ULP) transistor in advanced technology nodes (i.e. 40 nm and below) with a reduced off current (e.g. as indicated by the circle 110 in the graph of FIG. 1) whilst retaining adequate drive current for the application and still meeting pre-defined reliability requirements.

It will be appreciated that the process of fabricating a transistor comprises many hundreds of steps and the method described herein relates to changing only a small number of those steps and only these steps are described below. As is described in more detail below, the methods relate to changing the LDD (lightly doped drain, also written Ldd) implant dose and energy. In various examples, the methods may further relate to changing one or more of: the pocket implant dose, energy and the angle used for the pocket implant. Furthermore, a dual (rather than quad) implant scheme may be used for both the LDD and pocket implants.

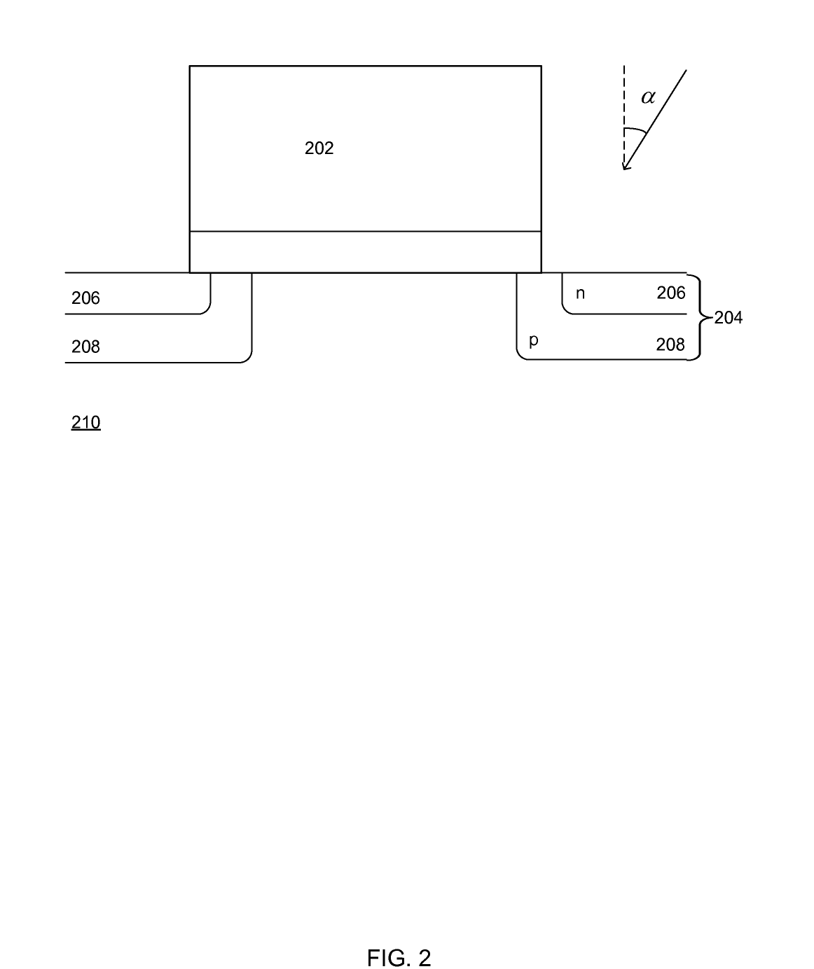

FIG. 2 is a schematic diagram of a cross-section through a MOSFET 200 which shows the gate 202 and source/drain extensions 204 which comprise high dose, shallow core LDD implants 206 which are the same polarity as the source/drain (e.g. n-doped in the example shown) and pocket (or halo) implants 208 which are of the opposite polarity. The source/drain extensions 204 are formed in a substrate 210 (a p-substrate in this example).

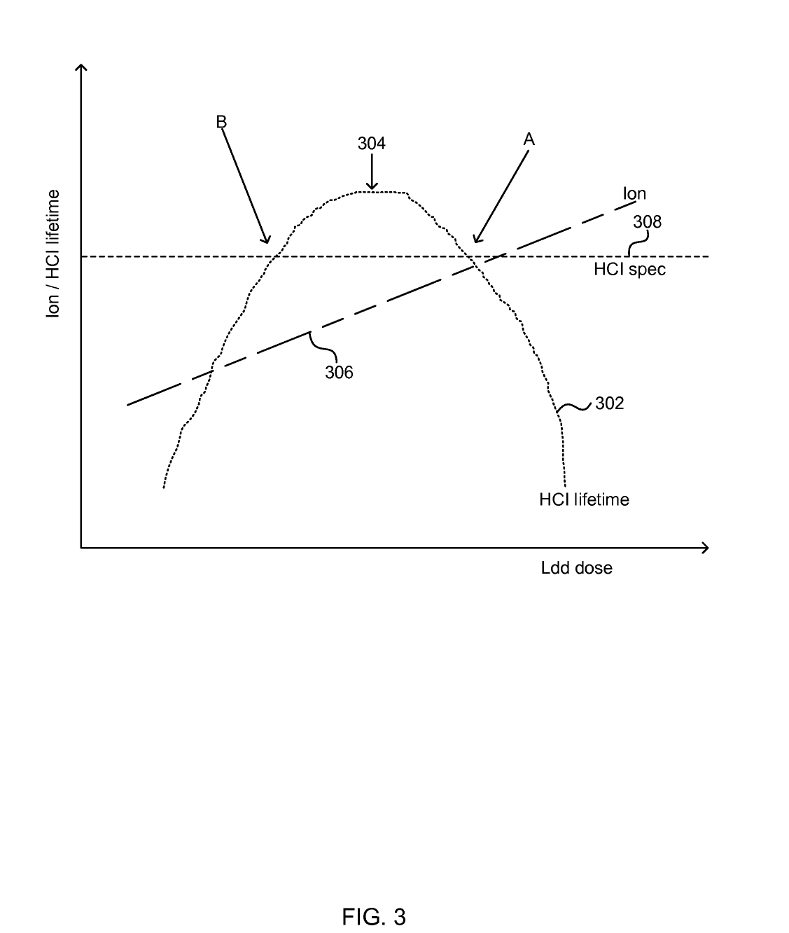

FIG. 3 is a graph showing the hot carrier injection (HCl) lifetime (on the y-axis) against the LDD dose (on the x-axis) and it can be seen from the trace 302 that the HCl lifetime initially increases with increased LDD dose, until a maximum lifetime is reached (as indicated by arrow 304) and then if the LDD dose is further increased the HCl lifetime reduces. The effect of the LDD dose on the on current, Ion, is also shown in the graph (line 306) and it can be seen that the on current increases with increasing LDD dose. A predefined HCl reliability requirement (or specification) is additionally shown in FIG. 3 as a horizontal dotted line 308. It will be appreciated that dependent upon the application, the position of this horizontal dotted line may move (i.e. up or down), but that it will still intersect with the trace 302 of HCl lifetime at two points.

Typically a MOSFET is optimized to maximize the value of Ion whilst still meeting the HCl reliability specification and as a result, MOSFETs are fabricated with an LDD dose indicated by the point A in FIG. 3 where the lifetime trace 302 intersects with the reliability requirement 308. At this point, if the LDD was increased further, the reliability requirement would no longer be met.

It has, however, been appreciated by the inventors that a MOSFET may alternatively be fabricated with an LDD dose at an alternative optimization point indicated by the point B in FIG. 3. At this point the lifetime trace 302 also intersects with the reliability requirement 308; however at this second optimization point (with point A being considered the standard or first optimization point), if the LDD dose was increased, the reliability requirement would still be met (unlike at the first optimization point, A) but if the LDD was reduced further, the reliability requirement would no longer be met.

This leap to optimize a transistor at point B rather than point A which has been made by the inventors is counter-intuitive and goes against the general teaching within the industry which has always worked towards increased values of Ion and increased speed (as indicated by the graph in FIG. 1, where the trend within any particular node has always been to progress to the right on the graph and increase speed of a device).

Although a transistor which is fabricated at (or close to) optimization point B in FIG. 3 has a reduced on current, Ion, this is not the significant consumer of power in the application space described herein (i.e. battery powered wireless devices which spend the majority of their time in a standby state). As described above, the majority of the power consumption is a result of junction leakage current whilst in the off state and this is reduced significantly by fabricating the transistor at (or near) point B rather than at point A in the graph of FIG. 3.

In an example, the LDD implant dose at optimization point B may be 10-20% of the LDD implant dose at optimization point A and therefore a transistor may be fabricated with a LDD implant dose which is 10-20% of the conventional implant dose (which may, for example, be 1E15 ion/cm²).

In addition to reducing the LDD implant dose, as described above, the MOSFET fabrication process may be further modified to further reduce the junction leakage current. In particular, in various examples, the energy used when implanting the LDD may be increased to up to four times the conventional value (e.g. between two and four times the conventional value). For example, for a PMOSFET, an energy of around 5 keV may typically be used when implanting BF₂ and for an NMOSFET, an energy of around 2 keV may typically be used when implanting As, and therefore these values may be increased to up to around 20 keV and 8 keV respectively.

Furthermore, in various examples, the pocket implant dose may be reduced in a similar manner to the LDD implant dose, for example to around 90% of the conventional pocket implant dose. Similarly, the energy used when implanting the pocket may be increased by up to 30% from conventional values. Examples of conventional values are, for a PMOSFET pocket, a dose of around 0.5E14 and an energy of around 55 keV may be used when implanting As and for an NMOSFET pocket, a dose of around 1E14 and an energy of around 9 keV may be used when implanting B.

In various examples, the angle used for the pocket implant may be increased (e.g. in addition to the other measures described above). The angle a used for the pocket implant 208 is indicated by arrow 212 in FIG. 2 and is specified with respect to vertical. Typically this angle is 37° and this angle may be increased to to 45° although it is ultimately limited by the shadowing effect of neighbouring devices. By reducing the pocket implant and increasing the angle used, the junction leakage current is reduced whilst maintaining the threshold voltage.

In various examples, one further modification to the fabrication process may be made through the use of dual implants rather than quad implants (as are commonly used). This change from quad to dual implants (for both the LDD implants and pocket implants) improves control and reduces variability but does not in itself affect the junction leakage current. Using dual implants rather than quad implants poses certain restrictions on the layout of transistors on a chip (and at a larger scale the entire wafer) as all the transistor gates must be aligned parallel to the same axis (i.e. parallel to each other and without any which are perpendicular to other gates).

In various examples, the operating voltage of the MOSFET may be reduced from the conventional operating voltage of 1.1V to 0.85V to further reduce gate leakage.

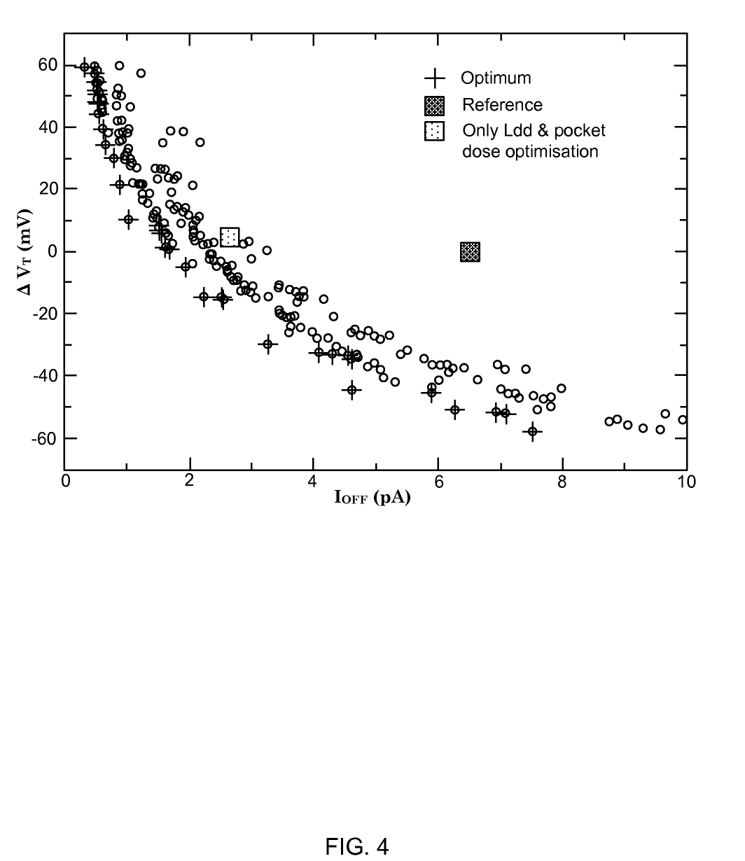

FIG. 4 is a graph which shows the results of making the changes to the MOSFET fabrication process as described above, with the resultant change in threshold voltage compared to a reference point 402, ΔV_{T} (on the y-axis) shown against the off current, I_{OFF} (on the x-axis). The reference point 402 for the standard process (without any of the changes described above) has a value of I_{OFF}˜6.5 pA. A corresponding point 404 showing the effect of optimizing only the LDD and pocket implant doses (i.e. reducing them both as described above) shows a reduction in I_{OFF} to below 3 pA (a reduction of more than a factor of two) with minimal change in the threshold voltage. The crosses show the optimum values where all the changes described above are made and the circles show further simulation results. These show that reductions in the off current of a factor of three can be achieved with little or no change in the threshold voltage. Although the results shown are for an NMOSFET, similar improvements can be made to PMOSFETS and similar results achieved.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to an item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. A method of fabricating a MOSFET using a CMOS technology node of 40 nm or less, the technology node comprising a first optimization point for LDD implant dose and a second optimization point for LDD implant dose, the first optimization point comprising a maximum LDD implant dose that satisfies an HCl reliability requirement and the second optimization point comprising a minimum LDD implant dose that satisfies the same HCl reliability requirement and the method comprising:
forming pocket implants in a MOSFET structure; and
forming LDD implants in the MOSFET structure using an LDD implant dose at the second optimization point.

2. The method according to claim 1, wherein the LDD implant dose at the second optimization point comprises a dose which is 10-20% of the LDD implant dose at the first optimization point.

3. The method according to claim 1, wherein the pocket implant dose at the second optimization point comprises a dose which is around 90% of the pocket implant dose at the first optimization point.

4. The method according to claim 1, wherein the LDD implant energy at the second optimization point comprises an energy which is 2-4 times the LDD implant energy at the first optimization point.

5. The method according to claim 1, wherein the pocket implant energy at the second optimization point comprises an energy which is around 30% more than the pocket implant energy at the first optimization point.

6. The method according to claim 1, wherein the pocket implants are formed using an angle of implantation of between 37° and 45°.

7. The method according to claim 1, wherein the LDD implants and the pocket implants are formed using dual implants.

8. The method according to claim 1, wherein the operating voltage of the MOSFET is 0.85V.
